(19) United States
(12) Patent Application Publication
(10) Pub. No.: US 2023/0387343 A1
(43) Pub. Date: Nov. 30, 2023

(54) METHOD FOR MANUFACTURING LIGHT-EMITTING DEVICE

(71) Applicant: NICHIA CORPORATION, Anan-shi (JP)

(72) Inventor: Koji NISHINO, Tokushima-shi (JP)

(73) Assignee: NICHIA CORPORATION, Anan-shi (JP)

(21) Appl. No.: 18/306,348

(22) Filed: Apr. 25, 2023

(30) Foreign Application Priority Data
May 24, 2022 (JP) 2022- 084439

(51) Int. Cl. H01L 33/00; H01L 21/66

(52) U.S. Cl. CPC H01L 33/005; H01L 22/12; H01L 22/14; H01L 2933/0066

(57) ABSTRACT

A method for manufacturing a light-emitting device includes: providing a plurality of first light-emitting elements, each comprising a joining portion containing gold; providing a support member including: a substrate, and a plurality of wiring portions, each disposed on the substrate and containing gold; joining the joining portions of the first light-emitting elements and corresponding wiring portions of the plurality of wiring portions under a first joining condition; evaluating whether at least one first light-emitting element of the plurality of first light-emitting elements is removable from the support member; evaluating electrical characteristics of each of the plurality of first light-emitting elements; and if the at least one first light-emitting element is removed from the support member, removing from the support member a first light-emitting element determined to be defective in the step of evaluating electrical characteristics of each of the plurality of first light-emitting elements.

### CROSS-REFERENCE TO RELATED APPLICATIONS

The present application claims priority under 35 U.S.C. § 119 to Japanese Patent Application No. 2022-084439, filed May 24, 2022, the contents of which are hereby incorporated by reference in their entirety.

### BACKGROUND

The present invention relates to a method for manufacturing a light-emitting device.

Japanese Patent Publication No. 2020-074005 discloses a light-emitting device in which a large number of semiconductor elements are mounted on one wiring substrate. In such a light-emitting device, if a defective product is present in the semiconductor elements mounted on the wiring substrate, the defective product needs to be removed and replaced with a non-defective product.

### SUMMARY

An object of the present invention is to provide a method for manufacturing a light-emitting device that allows for efficient removal of a light-emitting element determined to be defective.

According to an aspect of the present invention, a method for manufacturing a light-emitting device includes providing a plurality of first light-emitting elements, each comprising a first joining portion containing gold; providing a support member comprising a substrate, and a plurality of wiring portions, each disposed on the substrate and containing gold; joining the first joining portion and first wiring portion of the plurality of wiring portions under a first joining condition by bringing the first joining portion and the first wiring portion into contact with each other; evaluating whether at least one first light-emitting element of the plurality of first light-emitting elements is removable from the support member by bringing an adhesive member into contact with the at least one first light-emitting element and then moving the adhesive member in a direction from the support member toward the at least one first light-emitting element; evaluating electrical characteristics of each of the plurality of first light-emitting elements after said joining the first joining portion and first wiring portion of the plurality of wiring portions; and removing, if the at least one first light-emitting element is removed from the support member in said evaluating whether at least one first light-emitting element of the plurality of first light-emitting elements is removable, a first light-emitting element of the plurality of first light-emitting elements determined to be defective in said evaluating electrical characteristics of each of the plurality of first light-emitting elements from the support member.

The present disclosure can provide a method for manufacturing a light-emitting device that allows for efficient removal of light-emitting element determined to be defective.

### BRIEF DESCRIPTION OF THE DRAWINGS

FIG. 1 is a schematic cross-sectional view illustrating a step of a method for manufacturing a light-emitting device of an embodiment.

FIG. 2 is a schematic cross-sectional view illustrating a step of the method for manufacturing the light-emitting device of the embodiment.

FIG. 3 is a schematic cross-sectional view illustrating a step of the method for manufacturing the light-emitting device of the embodiment.

FIG. 4 is a schematic plan view illustrating a step of the method for manufacturing the light-emitting device of the embodiment.

FIG. 5A is a schematic cross-sectional view illustrating a step of the method for manufacturing the light-emitting device of the embodiment.

FIG. 5B is a schematic cross-sectional view illustrating a step of the method for manufacturing the light-emitting device of the embodiment.

FIG. 5C is a schematic cross-sectional view illustrating a step of the method for manufacturing the light-emitting device of the embodiment.

FIG. 6 is a schematic cross-sectional view illustrating a step of the method for manufacturing the light-emitting device of the embodiment.

FIG. 7 is a schematic cross-sectional view illustrating a step of the method for manufacturing the light-emitting device of the embodiment.

FIG. 8 is a schematic cross-sectional view illustrating a step of the method for manufacturing the light-emitting device of the embodiment.

FIG. 9 is a schematic cross-sectional view illustrating a step of the method for manufacturing the light-emitting device of the embodiment.

FIG. 10A is a schematic cross-sectional view illustrating a step of the method for manufacturing the light-emitting device of the embodiment.

FIG. 10B is a schematic cross-sectional view illustrating a step of the method for manufacturing the light-emitting device of the embodiment.

### DETAILED DESCRIPTION

Embodiments will be described below with reference to the drawings. In the drawings, the same constituent elements are denoted using the same reference characters. The drawings are diagrams that schematically illustrate embodiments, and thus, scales, intervals, positional relationships, and the like of members may be exaggerated, or some of the members may not be illustrated in the drawings. As a cross-sectional view, an end view illustrating only a cut surface may be illustrated.

In the following description, components having substantially the same function may be denoted by the same reference characters and a description thereof may be omitted. Further, terms indicating a specific direction or position (“upper,” “lower,” and other terms including those terms) may be used. However, these terms are used merely to make it easy to understand relative directions or positions in the referenced drawing. As long as the relative direction or position is the same as that described in the referenced drawing using the term such as “upper” or “lower,” in drawings other than the drawings of the present disclosure, actual products, and the like, components may not be arranged in the same manner as in the referenced drawing. In the present description, a positional relationship that expresses “up” (or “down”) includes a case in which an object is in contact and also a case in which an object is not in contact but located above (or below).

A method for manufacturing a light-emitting device of an embodiment includes a first providing step and a second providing step.

First Providing Step

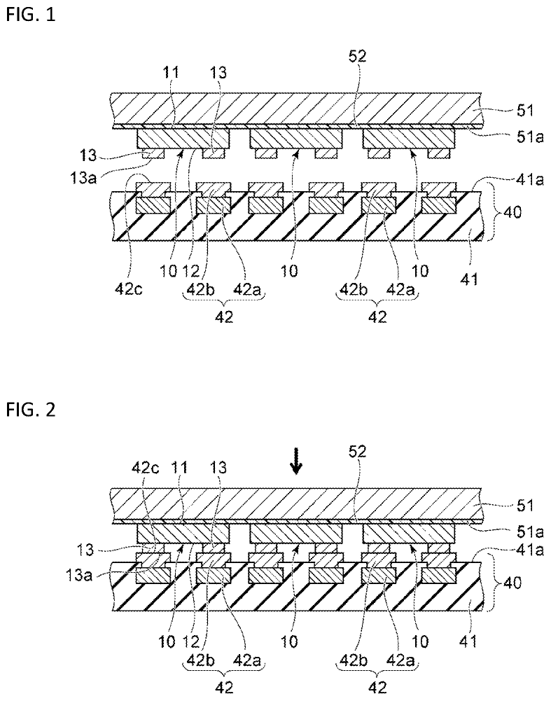

In the first providing step, as illustrated in FIG. 1, a plurality of first light-emitting elements 10 are provided. The first light-emitting element 10 includes a first surface 11 and a second surface 12 located opposite to the first surface 11. The first light-emitting element 10 includes first joining portions 13 disposed on the second surface 12 of the first light-emitting element 10.

Light from the first light-emitting element 10 is mainly extracted from the first surface 11. The first light-emitting element 10 emits any one of visible light, ultraviolet light, and infrared light. The first light-emitting element 10 emits blue light or green light, for example.

The first joining portion 13 is made of a metal material. The first joining portion 13 contains gold. At least a lower surface 13a of the first joining portion 13 is made of gold. Each of the first light-emitting elements 10 includes two first joining portions 13. One of the two first joining portions 13 serves as an anode electrode, and the other of the two first joining portions 13 serves as a cathode electrode.

The plurality of first light-emitting elements 10 are bonded to a first surface 51a of a transfer member 51. For example, a bonding member 52 is disposed on the first surface 51a of the transfer member 51, and the first surface 11 of each of the first light-emitting elements is bonded to the bonding member 52. Examples of the material that can be used for the transfer member 51 include sapphire, silicon, or glass. The bonding member 52 is, for example, a resin member. The first light-emitting elements 10 may also be directly bonded to the first surface 51a having bonding properties of the transfer member 51 without using the bonding member 52, or the first light-emitting elements 10 may also be adsorbed to the transfer member 51.

Second Providing Step

In the second providing step, as illustrated in FIG. 1, a support member 40 is provided. The support member 40 includes a substrate 41 and a plurality of wiring portions 42 disposed on the substrate 41.

The substrate 41 is made of an insulating material. Examples of the material that can be used for the substrate 41 include resin or ceramic.

For example, the wiring portion 42 includes a first wiring portion 42a and a second wiring portion 42b. The first wiring portion 42a is located inside the substrate 41. The second wiring portion 42b is located on the first wiring portion 42a in contact with the first wiring portion 42a and is electrically connected to the first wiring portion 42a. At least an upper surface 42c of the second wiring portion 42b is exposed from a second surface 41a of the substrate 41. The wiring portion 42 is made of a metal material. The wiring portion 42 contains gold. At least the upper surface 42c of the second wiring portion 42b is made of gold.

First Joining Step

The method for manufacturing the light-emitting device of the embodiment further includes a first joining step.

In the first joining step, as illustrated in FIG. 2, the first surface 51a of the transfer member 51 is opposed to the second surface 41a of the substrate 41 of the support member and each of the first joining portions 13 and corresponding one of the wiring portions 42 are brought into contact with each other and joined together under a first joining condition. Under the first joining condition, a load is applied in a direction from the transfer member 51 toward the support member 40, so that the lower surface 13a made of gold of the first joining portion 13 is brought into contact with the upper surface 42c made of gold of the second wiring portion 42b. Under the first joining condition, heat is further applied.

Under the first joining condition, the heating temperature is preferably in a range of to 200° C., for example. Under the first joining condition, the applied load is preferably in a range of 10 MPa to 150 MPa, for example. Under the first joining condition, the time period for applying the load is preferably in a range of 0.1 seconds to 10 seconds, for example.

In the first joining step, the lower surface 13a of the first joining portion 13 and the upper surface 42c of the second wiring portion 42b are joined to each other while the first joining portion 13 and the second wiring portion 42b substantially maintain their respective shapes before joining. For example, if a recessed portion is formed in the upper surface 42c of the second wiring portion 42b before joining, a gap may remain between the first joining portion 13 and the recessed portion of the second wiring portion 42b. By joining the first joining portion 13 and the second wiring portion 42b under the first joining condition, the first joining portion 13 and the second wiring portion 42b are electrically connected to each other, but a mechanical joining strength is lower than a joining strength under a second joining condition to be described below. Hereinafter, such a state achieved under the first joining condition is referred to as a “temporarily joined state.”

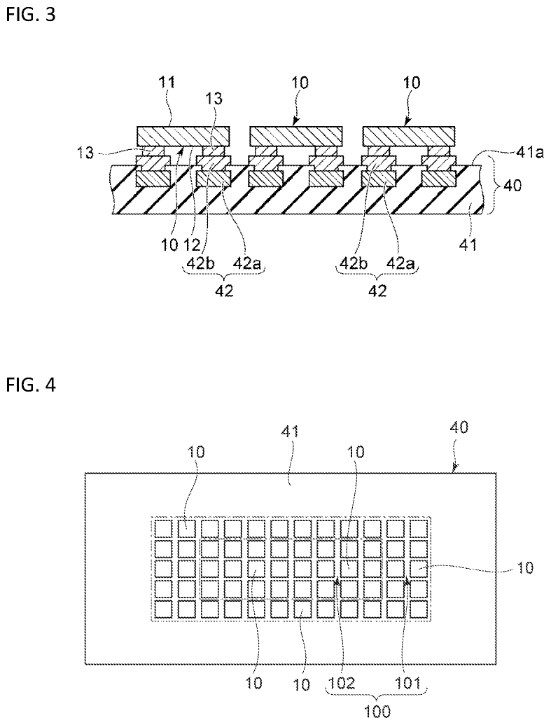

After the first joining step, the transfer member 51 is separated from the first light-emitting element 10. At this time, by setting the joining strength in the temporarily joined state to be higher than the joining strength between the bonding member 52 and the first surface 11 of the first light-emitting element 10, the transfer member 51 can be easily separated from the first light-emitting element 10. Thus, as illustrated in FIGS. 3 and 4, a structure, in which the plurality of first light-emitting elements 10 are disposed on the support member 40 in the temporarily joined state, is obtained.

After the first joining step, as illustrated in FIG. 4, an element region 100, in which the plurality of first light-emitting elements 10 are disposed on the substrate 41 in a matrix form, is formed. In FIG. 4, the element region 100 is a region inside the one-dot chain line. An interval between the plurality of first light-emitting elements 10 disposed in the element region 100 is equal to or less than 30 for example. For example, the shape of the first light-emitting element 10 in a plan view is rectangular, and the length of one side of the first light-emitting element 10 is in a range of 10 μm to 100 μm. The number of the first light-emitting elements 10 disposed in the element region 100, for example, is equal to or higher than 50 and can be in a range of 50 to 100000, preferably in a range of 10000 to 50000.

First Evaluation Step

The method for manufacturing the light-emitting device of the embodiment further includes a first evaluation step after the first joining step.

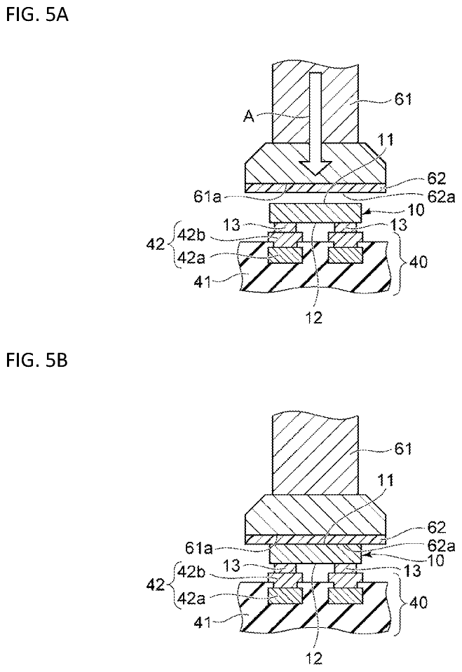

In the first evaluation step, an adhesive member 62 is moved in a direction A from the first light-emitting elements 10 toward the support member 40 as illustrated in FIG. 5A and is brought into contact with at least one first light-emitting element 10 as illustrated in FIG. 5B. An adhesive surface 62a of the adhesive member 62 is brought into contact with the first surface 11 of the at least one first light-emitting element 10 to be evaluated in the first evaluation step. The first surface 11 of the first light-emitting element 10 is bonded to the adhesive surface 62a of the adhesive member 62.

The adhesive member 62 is, for example, a resin member and is fixed to a lower surface 61a of a first member 61. The first member 61 is made of, for example, a metal material. The area of the lower surface 61a of the first member 61 is greater than the area of the first surface 11 of the first light-emitting element 10. The area of the adhesive surface 62a of the adhesive member 62 is equal to or less than the area of the lower surface 61a of the first member 61 and is greater than the area of the first surface 11 of the first light-emitting element 10. For example, in a state in which the adhesive surface 62a is brought into contact with the first surface 11 of one first light-emitting element 10 to be evaluated, the area of the lower surface 61a of the first member 61 and the area of the adhesive surface 62a of the adhesive member 62 are set so that the adhesive member 62 does not come into contact with other first light-emitting elements 10 adjacent to the first light-emitting elements 10 to be evaluated.

In the first evaluation step, after the adhesive member 62 is brought into contact with the at least one first light-emitting element 10, the adhesive member 62 is moved in a direction B from the support member 40 toward the first light-emitting element 10 as illustrated in FIG. 5C, thereby allowing for evaluation of whether the at least one first light-emitting element 10 can be removed from the support member 40.

By moving the first member 61 in the direction B, the adhesive member 62 fixed to the lower surface 61a of the first member 61 is moved in the direction B. With the movement of the adhesive member 62 in the direction B, a force (tensile load) in the direction B away from the support member 40 is also applied to the first light-emitting element 10 including the first surface 11 bonded to the adhesive surface 62a of the adhesive member 62. Thus, a temporary joining strength between the first joining portion 13 and the second wiring portion 42b can be confirmed to be a strength at which a first light-emitting element 10 determined to be defective in a step to be described below can be removed from the support member 40 by the first joining portion 13 of the first light-emitting element 10 being separated from the second wiring portion 42b of the support member 40, and the temporary joining strength in the first joining step is evaluated to be appropriate. By confirming that the first light-emitting element 10 can be removed from the support member 40 after the first joining step, steps subsequent to the first joining step can be efficiently performed, so that when a first light-emitting element 10 determined to be defective occurs, the defective product can be efficiently replaced. In the first evaluation step, if the first joining portion 13 of the first light-emitting element 10 is not separated from the second wiring portion 42b of the support member 40, the evaluation fails.

Second Evaluation Step

The method for manufacturing the light-emitting device of the embodiment further includes a second evaluation step after the first joining step.

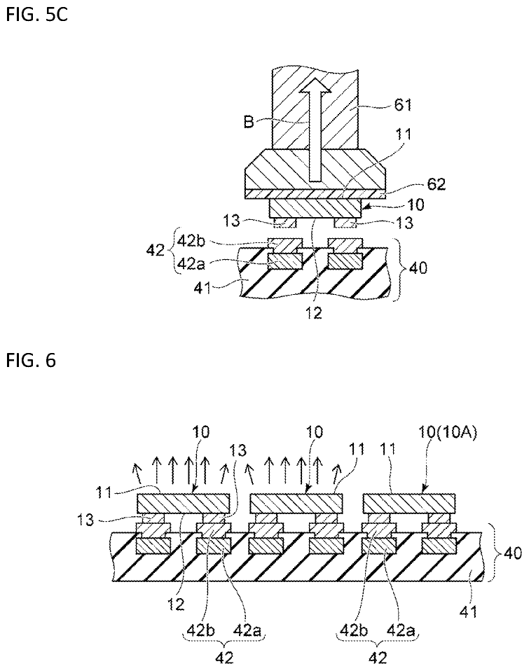

In the second evaluation step, electrical characteristics of the plurality of first light-emitting elements 10 are evaluated. As illustrated in FIG. 6, electric power is supplied to the plurality of first light-emitting elements 10 via the wiring portions 42, and the electrical characteristics of the first light-emitting elements 10 are evaluated. The electrical characteristics to be evaluated are, for example, the brightness of light emitted by the first light-emitting element 10. In the second evaluation step, the plurality of first light-emitting elements 10 joined to the support member 40 in the temporarily joined state are classified into non-defective products and defective products. For example, a first light-emitting element 10 having brightness equal to or higher than a reference value is determined to be a non-defective product, and a first light-emitting element 10 having brightness lower than the reference value is determined to be a defective product. Hereinafter, a first light-emitting element 10 determined to be defective is also referred to as a first light-emitting element 10A.

The second evaluation step is performed after the first evaluation step. Alternatively, the second evaluation step is performed before the first evaluation step.

In the second evaluation step, because each of the plurality of first light-emitting elements 10 is electrically connected to the wiring portion 42, the electrical characteristics of the plurality of first light-emitting elements 10 can be simultaneously evaluated via the wiring portions 42.

Removing First Light-Emitting Element Determined to be Defective from Support Member

The method for manufacturing the light-emitting device of the embodiment further includes a step of removing, when at least one first light-emitting element 10 is removed from the support member 40 in the first evaluation step, the first light-emitting element 10A determined to be defective in the second evaluation step from the support member 40.

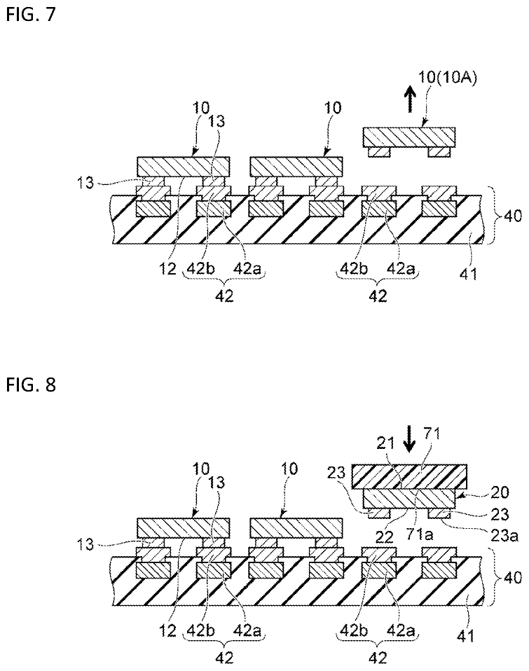

As illustrated in FIG. 7, the first joining portion 13 of the first light-emitting element determined to be defective is separated from the second wiring portion 42b of the support member 40, thereby removing the first light-emitting element 10A determined to be defective from the support member 40. For example, the first light-emitting element 10A is heated by irradiating the first light-emitting element 10A with laser light. Thus, thermal stress is applied to an interface between the first joining portion 13 of the first light-emitting element 10A and the second wiring portion 42b, and the first joining portion 13 of the first light-emitting element 10A is removed from the second wiring portion 42b.

The joining strength between the first joining portion 13 and the second wiring portion 42b at which the first light-emitting element 10A can be removed from the support member 40 by laser light irradiation is equal to or less than 40 MPa, for example. In order to reliably remove the first light-emitting element 10A by the laser light irradiation, the joining strength between the first joining portion 13 and the second wiring portion 42b in the first joining step is preferably set to be equal to or less than the 30 MPa, for example. In the first evaluation step, the bonding strength between the adhesive member 62 and the first light-emitting element 10 is set to be greater than the joining strength between the first joining portion 13 and the second wiring portion 42b in the first joining step, for example, to be equal to or greater than 31 MPa.

The first light-emitting element 10A may be removed by, for example, bonding the first light-emitting elements 10A to an adhesive member. The first light-emitting element 10A may also be removed by suction with a suction device.

Second Joining Step

The method for manufacturing the light-emitting device of the embodiment further includes a second joining step.

In the second joining step, second light-emitting elements 20 are disposed as illustrated in FIG. 8 at the position where the first light-emitting element 10A determined to be defective in the second evaluation step is removed and at the position where at least one first light-emitting element 10 is removed in the first evaluation step.

The second light-emitting element 20 has the same configuration as the first light-emitting element 10. The second light-emitting element 20 includes a first surface 21 and second joining portions 23 disposed on a second surface 22 located opposite to the first surface 21. Light from the second light-emitting element 20 is mainly extracted from the first surface 21. The second light-emitting element 20 emits visible light or ultraviolet light. The second joining portion 23 is made of a metal material. The second joining portion 23 contains gold. At least a lower surface 23a of the second joining portion 23 is made of gold. The second light-emitting element 20 includes two second joining portions 23. One of the two second joining portions 23 serves as an anode electrode and the other of the two second joining portions 23 serves as a cathode electrode.

As illustrated in FIG. 8, in a state in which the first surface 21 of the second light-emitting element 20 is bonded to an adhesive lower surface 71a of a second member 71, the second light-emitting element 20 is moved toward the support member 40 together with the second member 71 and is disposed on the support member 40. The second member 71 is, for example, a resin member. The second joining portions 23 of the second light-emitting elements 20 are brought into contact with and joined to the corresponding second wiring portions 42b at the position where the first light-emitting element 10A determined to be defective in the second evaluation step is removed and at the position where the first light-emitting element 10 is removed by using the adhesive member 62 in the first evaluation step. The joining condition in the second joining step can be set to the same condition as the first joining condition in the first joining step.

Third Joining Step

The method for manufacturing the light-emitting device of the embodiment further includes a third joining step.

In the third joining step and after the second joining step, the first joining portion 13 of the first light-emitting element 10 is joined to the second wiring portion 42b and the second joining portion 23 of the second light-emitting element 20 is joined to the second wiring portion 42b, under a second joining condition.

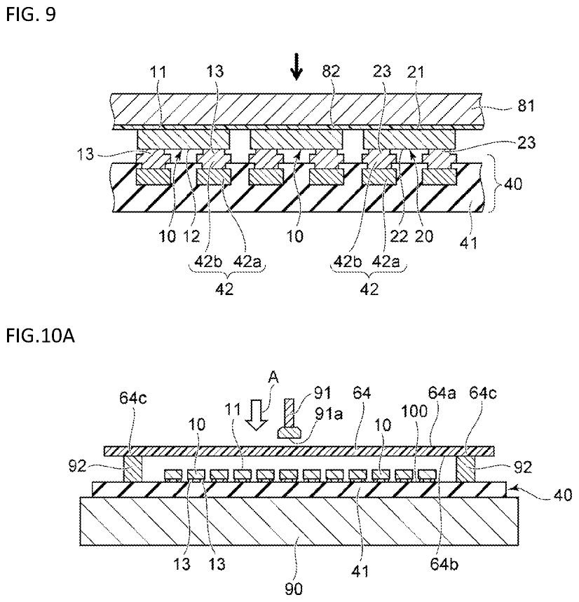

As illustrated in FIG. 9, the first light-emitting element 10 and the second light-emitting element 20 are heated while applying a load in a direction toward the support member 40 by using a third member 81. Thus, the first joining portion 13 of the first light-emitting element 10 and the second wiring portion 42b in the temporarily joined state are joined to each other, and the second joining portion 23 of the second light-emitting element newly disposed in the second joining step and the second wiring portion 42b are joined to each other. As the third member 81, the transfer member 51 used in the first joining step may also be used again. For example, the first surface 11 of the first light-emitting element and the first surface 21 of the second light-emitting element 20 are bonded to a lower surface of the third member 81 via a bonding member 82.

According to one embodiment, the temperature under the second joining condition is higher than the temperature under the first joining condition. Alternatively, the load under the second joining condition is greater than the load under the first joining condition. Alternatively, the temperature under the second joining condition is higher than the temperature under the first joining condition, and the load under the second joining condition is greater than the load under the first joining condition. Alternatively, the time period for applying the load under the second joining condition is longer than the time period for applying the load under the first joining condition.

Under the second joining condition, the heating temperature is preferably in a range of 200° C. to 300° C., for example. Under the second joining condition, the applied load is preferably in a range from 40 MPa to 200 MPa, for example. Under the second joining condition, the time period for applying the load is preferably in a range of 1 second to 60 seconds, for example.

By the third joining step, the first joining portion 13 of the first light-emitting element 10 and the second wiring portion 42b are joined together with a strength greater than that in the temporarily joined state, and the second joining portion 23 of the second light-emitting element 20 and the second wiring portion 42b are joined together with a strength greater than that in the temporarily joined state. By the third joining step, the first joining portion 13 and the second wiring portion 42b joined together and the second joining portion 23 and the second wiring portion 42b joined together are integrated with each other, and most of the interface therebetween disappears. Furthermore, if gaps are generated at the interface, most of the gaps disappear. The first joining portion 13 and the second wiring portion 42b are electrically connected to each other, and the second joining portion 23 and the second wiring portion 42b are electrically connected to each other. The mechanical joining strength between the first joining portion 13 and the second wiring portion 42b and the mechanical joining strength between the second joining portion 23 and the second wiring portion 42b are greater than those in the temporarily joined state in the first joining step. Such a state achieved by the third joining step is referred to as a “mainly joined state.” After the third joining step, the third member 81 is separated from the first light-emitting element 10 and the second light-emitting element 20.

When there is no first light-emitting element 10A determined to be defective in the above-described second evaluation step illustrated in FIG. 6, the step of removing a defective product and the step of disposing the second light-emitting element 20 at the position where the defective product is removed are not performed. In the second joining step illustrated in FIG. 8, the second light-emitting element 20 is disposed only at the position where the first light-emitting element 10 is removed by using the adhesive member 62 in the first evaluation step.

As illustrated in FIG. 4, the element region 100 of the substrate 41 on which the plurality of first light-emitting elements 10 are disposed after the first joining step includes an outer peripheral portion 101 and an inner portion 102. The inner portion 102 is surrounded by the outer peripheral portion 101 and is located inside the outer peripheral portion 101, in a plan view. In FIG. 4, the inner portion 102 is a region inside the two-dot chain line, and the outer peripheral portion 101 is a region between the one-dot chain line and the two-dot chain line. The first light-emitting elements 10 disposed in the outer peripheral portion 101 include at least one first light-emitting element 10 located at the outermost periphery of the element region 100 among the first light-emitting elements 10 disposed in the element region 100. The first light-emitting elements 10 disposed in the outer peripheral portion 101 may include a plurality of first light-emitting elements 10 located between the outermost periphery and the inner portion 102 of the element region 100 among the first light-emitting elements disposed in the element region 100. In one direction in which the plurality of first light-emitting elements 10 are arranged in the element region 100, the number of first light-emitting elements 10 disposed between the outermost periphery and the inner portion 102 of the element region 100 as the first light-emitting elements 10 disposed in the outer peripheral portion 101 can be in a range from 2 to 20, for example.

Among the plurality of first light-emitting elements 10 disposed in the element region 100, temporary joining strength of the first light-emitting elements 10 disposed in the inner portion 102 may be greater than temporary joining strength of the first light-emitting elements 10 disposed in the outer peripheral portion 101. Consequently, if the adhesive member 62 is brought into contact with the first light-emitting element 10 located in the inner portion 102 and then the first light-emitting elements 10 located in the inner portion 102 can be removed from the support member 40 in the first evaluation step, the first light-emitting element 10A determined to be defective in the second evaluation step can be easily removed wherever the first light-emitting element 10A is located. The temporary joining strength may be reduced from the center to the outer periphery of the element region 100. Thus, in the first evaluation step, the first light-emitting element 10 with which the adhesive member 62 is brought into contact is preferably a first light-emitting element 10 located in a central region of the element region 100 among the first light-emitting elements 10 located in the inner portion 102. With this configuration, the first evaluation step can be performed on a first light-emitting element 10 having a greater temporary joining strength, so that the first light-emitting element 10A can be more easily removed.

In the first joining step, when the first joining portion 13 and the second wiring portion 42b are joined to each other by using, for example, a joining material containing tin, a residue of the joining material may remain on the upper surface 42c of the second wiring portion 42b after the first light-emitting element 10A determined to be defective is removed. In the first joining step, when the first joining portion 13 and the second wiring portion 42b are joined to each other by forming, for example, plating, a residue of the plating material may remain on the upper surface 42c of the second wiring portion 42b after the first light-emitting element 10A determined to be defective is removed. Due to the residue of the joining material or the plating material, the joining strength between the second light-emitting element 20 and the second wiring portion 42b may be reduced in the second joining step. In the joining by using the joining material containing tin or the joining by the plating, once the joining is performed, it is difficult to remove the joining material or the plating material after the joining.

In the present embodiment, in the first joining step, the gold-containing section of the first joining portion 13 of the first light-emitting element 10 and the gold-containing section of the second wiring portion 42b are directly joined to each other. In the step of removing the first light-emitting element 10A determined to be defective, because the bonding is released at an interface between the gold-containing section of the first joining portion 13 and the gold-containing section of the second wiring portion 42b, a residue is less likely to remain on the upper surface 42c of the second wiring portion 42b. Thus, when the second light-emitting element 20 is joined to the second wiring portion 42b in the second joining step, the joining strength between the second light-emitting element 20 and the second wiring portion 42b can be increased.

Another Example of First Evaluation Step

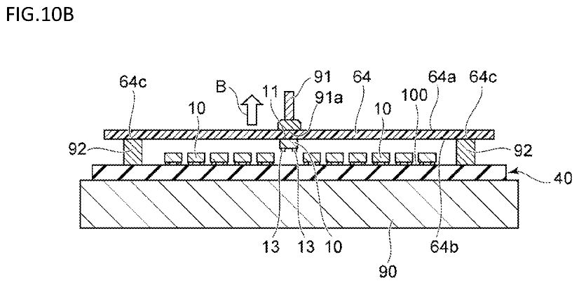

In another example of the first evaluation step, an adhesive member 64 illustrated in FIG. 10A is used. The adhesive member 64 is, for example, a resin member. The adhesive member 64 includes a lower surface 64b facing the first surface 11 of each of the first light-emitting elements 10 and an upper surface 64a located opposite to the lower surface 64b. Both the upper surface 64a and the lower surface 64b are adhesive. The area of each of the upper surface 64a and the lower surface 64b is greater than the area of the element region 100 of the substrate 41 on which the plurality of first light-emitting elements 10 are disposed.

The support member 40 is disposed on a base 90. The adhesive member 64 is disposed above the support member 40 via a frame member 92. The shape of the adhesive member 64 in a plan view is, for example, circular. The shape of the frame member 92 in a plan view is, for example, annular. A lower surface 64b of an outer peripheral portion 64c of the adhesive member 64 is disposed on the frame member 92. A region of the lower surface 64b of the adhesive member 64 located inside the outer peripheral portion 64c faces the first surface 11 of each of the first light-emitting elements 10 with a gap therebetween. In the first evaluation step, a fourth member 91 is moved in the direction A from above the upper surface 64a of the adhesive member 64 toward the first light-emitting element 10, and a lower surface 91a of the fourth member 91 is brought into contact with the upper surface 64a of the adhesive member 64. The fourth member 91 is made of, for example, a metal material. After the lower surface 91a of the fourth member 91 is brought into contact with the upper surface 64a of the adhesive member 64, the fourth member 91 is further moved in the direction A. Thus, the adhesive member 64 is pressed by the fourth member 91 and is bent toward the support member 40, and the lower surface 64b of the adhesive member 64 comes into contact with the first surface 11 of at least one first light-emitting element 10 to be evaluated. A part of the adhesive member 64 is interposed between the lower surface 91a of the fourth member 91 and the first surface 11 of the first light-emitting element 10. In a portion where the adhesive member 64 is interposed between the fourth member 91 and the first light-emitting element 10, the lower surface 91a of the fourth member 91 is bonded to the upper surface 64a of the adhesive member 64, and the first surface 11 of the first light-emitting element 10 is bonded to the lower surface 64b of the adhesive member 64.

In a state in which the upper surface 64a of the adhesive member 64 is bonded to the fourth member 91 and the lower surface 64b of the adhesive member 64 is bonded to the first surface 11 of the first light-emitting element 10, the fourth member 91 is moved in the direction B from the support member 40 toward the first light-emitting element 10 as illustrated in FIG. 10B. With this configuration, whether the first light-emitting element 10 can be removed from the support member 40 is evaluated.

With the movement of the fourth member 91 in the direction B, a force (tensile load) in the direction B away from the support member 40 is also applied to the adhesive member 64 and the first light-emitting element 10. Thus, the temporary joining strength between the first joining portions 13 and the second wiring portion 42b can be confirmed to be a strength at which a first light-emitting element 10 determined to be defective in the second evaluation step can be removed from the support member 40 by the first joining portion 13 of the first light-emitting element 10 being separated from the second wiring portion 42b of the support member 40. Thus, the temporary joining strength in the first joining step is evaluated to be appropriate.

If the area of a surface (the first surface 11 in the present embodiment) of the first light-emitting element 10, which is in contact with the adhesive member, is small, it is difficult to ensure a desired bonding strength between the adhesive member and the first light-emitting element 10.

The area of the lower surface 64b of the adhesive member 64 illustrated in FIG. 10A and the 10B, which faces the first light-emitting elements 10, is greater than the area of the first surface 11 of one of the first light-emitting elements 10. Thus, by setting the area of the lower surface 91a of the fourth member 91 to be greater than the total area of the first surfaces 11 of two or more first light-emitting elements 10, the lower surface 64b of the adhesive member 64 can be simultaneously brought into contact with the first surfaces 11 of the two or more first light-emitting elements 10 to evaluate whether the two or more first light-emitting elements 10 can be removed from the support member 40. With this configuration, even though the area of a surface of one first light-emitting element 10, which is in contact with the adhesive member 64, is small, a desired bonding strength between the adhesive member 64 and the first light-emitting element 10 can be ensured.

The embodiments of the present invention have been described above with reference to specific examples. However, the present invention is not limited to these specific examples. All aspects that can be practiced by a person skilled in the art modifying the design as appropriate based on the above-described embodiments of the present invention are also included in the scope of the present invention, as long as they encompass the spirit of the present invention. In addition, in the spirit of the present invention, a person skilled in the art can conceive of various examples of changes and modifications, and those examples of changes and modifications will also fall within the scope of the present invention.

What is claimed is:

1. A method for manufacturing a light-emitting device, the method comprising:
providing a plurality of first light-emitting elements, each comprising a joining portion containing gold;
providing a support member comprising:
a substrate, and
a plurality of wiring portions, each disposed on the substrate and containing gold;
joining the joining portions of the first light-emitting elements and corresponding wiring portions of the plurality of wiring portions under a first joining condition by bringing the joining portions of the first light-emitting elements and the corresponding wiring portions into contact with each other;
evaluating whether at least one first light-emitting element of the plurality of first light-emitting elements is removable from the support member by bringing an adhesive member into contact with the at least one first light-emitting element and then moving the adhesive member in a direction from the support member toward the at least one first light-emitting element;
after the step of joining the joining portions of the first light-emitting elements and the corresponding wiring portions, evaluating electrical characteristics of each of the plurality of first light-emitting elements; and
if the at least one first light-emitting element is removed from the support member in the step of evaluating whether the at least one first light-emitting element is removable, removing from the support member a first light-emitting element of the plurality of first light-emitting elements determined to be defective in the step of evaluating electrical characteristics of each of the plurality of first light-emitting elements.

2. The method for manufacturing the light-emitting device according to claim 1, further comprising:
joining a plurality of joining portions of a plurality of second light-emitting elements and a plurality of corresponding wiring portions of the plurality of wiring portions by disposing the second light-emitting elements at a plurality of corresponding positions, and by bringing the joining portions of the plurality of second light-emitting elements and the corresponding wiring portions into contact with each other, wherein:
each of the joining portions of the plurality of second light-emitting elements contains gold, and
the corresponding positions comprise a first position where the first light-emitting element determined to be defective in the step of evaluating electrical characteristics of each of the plurality of first light-emitting elements is removed and a second position where the at least one first light-emitting element is removed in the step of evaluating whether the at least one first light-emitting element of the plurality of first light-emitting elements is removable.

3. The method for manufacturing the light-emitting device according to claim 2, further comprising:
after the step of joining the joining portions of the second light-emitting elements and the corresponding wiring portions of the plurality of wiring portions, joining the joining portions of the plurality of first light-emitting elements and the corresponding wiring portions as well as the joining portions of the plurality of second light-emitting elements and the corresponding wiring portions, under a second joining condition, wherein:
a temperature under the second joining condition is higher than a temperature under the first joining condition, and/or a load under the second joining condition is greater than a load under the first joining condition.

4. The method for manufacturing the light-emitting device according to claim 1, wherein:
an element region comprising the plurality of first light-emitting elements disposed on the substrate is formed after the step of joining the joining portions of the plurality of first light-emitting elements and the corresponding wiring portions,
in a plan view, the element region comprises an outer peripheral portion, and an inner portion surrounded by the outer peripheral portion and located inside the outer peripheral portion, and
in the step of evaluating whether the at least one first light-emitting element of the plurality of first light-emitting elements is removable, the adhesive member is brought into contact with the at least one first light-emitting element located in the inner portion.

5. The method for manufacturing the light-emitting device according to claim 2, wherein:
an element region comprising the plurality of first light-emitting elements disposed on the substrate is formed after the step of joining the joining portions of the plurality of first light-emitting elements and the corresponding wiring portions,
in a plan view, the element region comprises an outer peripheral portion, and an inner portion surrounded by the outer peripheral portion and located inside the outer peripheral portion, and
in the step of evaluating whether the at least one first light-emitting element of the plurality of first light-emitting elements is removable, the adhesive member is brought into contact with the at least one first light-emitting element located in the inner portion.

6. The method for manufacturing the light-emitting device according to claim 3, wherein:
an element region comprising the plurality of first light-emitting elements disposed on the substrate is formed after the step of joining the joining portions of the plurality of first light-emitting elements and the corresponding wiring portions,
in a plan view, the element region comprises an outer peripheral portion, and an inner portion surrounded by the outer peripheral portion and located inside the outer peripheral portion, and
in the step of evaluating whether the at least one first light-emitting element of the plurality of first light-emitting elements is removable, the adhesive member is brought into contact with the at least one first light-emitting element located in the inner portion.

7. The method for manufacturing the light-emitting device according to claim 4, wherein:
an interval between the plurality of first light-emitting elements disposed in the element region is equal to or less than 30 μm.

8. The method for manufacturing the light-emitting device according to claim 5, wherein:
an interval between the plurality of first light-emitting elements disposed in the element region is equal to or less than 30 μm.

9. The method for manufacturing the light-emitting device according to claim 6, wherein:
an interval between the plurality of first light-emitting elements disposed in the element region is equal to or less than 30 μm.

10. The method for manufacturing the light-emitting device according to claim 1, wherein:
in a plan view, a shape of each of the plurality of first light-emitting elements is rectangular, and
a length of one side of each of the plurality of first light-emitting elements is in a range of 30 μm to 100 μm.

11. The method for manufacturing the light-emitting device according to claim 2, wherein:
in a plan, a shape of each of the plurality of first light-emitting elements view is rectangular, and
a length of one side of each of the plurality of first light-emitting elements is in a range of 30 μm to 100 μm.

12. The method for manufacturing the light-emitting device according to claim 3, wherein:
in a plan view, a shape of each of the plurality of first light-emitting elements is rectangular, and
a length of one side of each of the plurality of first light-emitting elements is in a range of 30 μm to 100 μm.

13. The method for manufacturing the light-emitting device according to claim 3, wherein:
a temperature under the first joining condition is in a range of 80° C. to 200° C., and
a temperature under the second joining condition is in a range of 200° C. to 300° C.

14. The method for manufacturing the light-emitting device according to claim 6, wherein:
a temperature under the first joining condition is in a range of 80° C. to 200° C., and
a temperature under the second joining condition is in a range of 200° C. to 300° C.

15. The method for manufacturing the light-emitting device according to claim 3, wherein:
an applied load under the first joining condition is in a range of 10 MPa to 150 MPa, and
an applied load under the second joining condition is in a range of 40 MPa to 200 MPa.

16. The method for manufacturing the light-emitting device according to claim 6, wherein:
an applied load under the first joining condition is in a range of 10 MPa to 150 MPa, and
an applied load under the second joining condition is in a range of 40 MPa to 200 MPa.

17. The method for manufacturing the light-emitting device according to claim 3, wherein:
a time period during which the load is applied under the first joining condition is in a range of 0.1 seconds to 10 seconds, and
a time period during which the load is applied under the second joining condition is in a range of 1 seconds to 60 seconds.

18. The method for manufacturing the light-emitting device according to claim 6, wherein:
a time period during which the load is applied under the first joining condition is in a range of 0.1 seconds to 10 seconds, and
a time period during which the load is applied under the second joining condition is in a range of 1 seconds to 60 seconds.
